(19) United States
(12) Patent Application Publication
(10) Pub. No.: US 2025/0351280 A1
(43) Pub. Date: Nov. 13, 2025

(54) DISPLAY DEVICE

(71) Applicants: Samsung Display Co., LTD., Yongin-si (KR); UIF (University Industry Foundation), Yonsei University, Seoul (KR)

(72) Inventors: TAEWOONG KIM, Yongin-si (KR); Jong Hyun AHN, Seoul (KR); Beomjin KIM, Seoul (KR); JIN HEE NA, Yongin-si (KR); Seokmin YUN, Seoul (KR); CHEOL JANG, Yongin-si (KR)

(21) Appl. No.: 19/092,683

(22) Filed: Mar. 27, 2025

(30) Foreign Application Priority Data
May 13, 2024 (KR) 10-2024-0062675

(51) Int. Cl. H05K 5/02

(52) U.S. Cl. CPC H05K 5/0217

(57) ABSTRACT

A display device includes a rolling shaft having a step and a display module coupled to the rolling shaft to fill the step. The display module includes a display panel and an auxetic structure disposed below the display panel. The auxetic structure includes a first area and a second area having a higher elastic modulus than the first area, and a flat area is disposed between a rotational axis and the second area in a state in which the display module is rolled on the rolling shaft.

This application claims priority to Korean Patent Application No. 10-2024-0062675, filed on May 13, 2024, and all the benefits accruing therefrom under 35 U.S.C. § 119, the content of which in its entirety is herein incorporated by reference.

### BACKGROUND

Embodiments of the present disclosure described herein relate to a display device, and more particularly, relate to a rollable display device.

Electronic devices, such as smart phones, tablet computers, notebook computers, car navigation units, smart televisions, and the like, are being developed. The electronic devices include a display device to provide information.

Various types of display devices are being developed to satisfy users' UX/UI. The development of flexible display devices, such as foldable display devices and rollable display devices, among them has been activated.

### SUMMARY

Embodiments of the present disclosure provide a display device for decreasing a crease and improving surface quality.

According to an embodiment, a display device includes a rolling shaft having a rotational axis defined therein and including a side surface including a curved area and a flat area and a display module coupled to the side surface of the rolling shaft such that a side surface of the display module faces the flat area. The display module includes a display panel, an auxetic structure disposed below the display panel, and a support layer that is disposed below the auxetic structure and that includes a plurality of support sticks. The auxetic structure includes a first area and a second area having a higher elastic modulus than the first area. The flat area is disposed between the rotational axis and the second area in a state in which the display module is rolled on the rolling shaft.

The first area may have an elastic modulus of 50 megapascals (MPa) to 400 MPa, and the second area may have an elastic modulus of 500 MPa to 1 gigapascal (GPa).

The curved area may be disposed clockwise from a first point having a first radius to a second point having a second radius greater than the first radius on a cross-section perpendicular to the rotational axis, and the curved area may have a gradually increasing radius from the first point toward the second point in a clockwise direction.

The curved area may be disposed clockwise from a first point having a first radius to a second point having a second radius greater than the first radius on a cross-section perpendicular to the rotational axis, and the curved area may include a first area having a gradually increasing radius from the first point to a third point between the first point and the second point in a clockwise direction and a second area having a constant radius from the third point to the second point in a clockwise direction.

The auxetic structure may include a first line that defines first unit cells disposed in the first area and a second line that defines second unit cells disposed in the second area, and the second line may have a greater line width than the first line.

The first unit cells and the second unit cells may have substantially the same pitch.

The first line may have a line width of 30 micrometers (μm) to 60 μm, and the second line may have a line width of 60 μm to 100 μm.

The auxetic structure may include a first line that defines first unit cells disposed in the first area and a second line that defines second unit cells disposed in the second area, and the second unit cells may each have a smaller pitch than each of the first unit cells.

The first line and the second line may have substantially the same line width or substantially the same thickness.

The second area may include a first modulus area and second modulus areas disposed on opposite sides of the first modulus area in a state in which the display module is unrolled from the rolling shaft. The first modulus area may have a higher elastic modulus than the second modulus areas.

The display device may further include an adhesive layer disposed between the display panel and the support layer. The auxetic structure may be disposed inside the adhesive layer.

The support layer may further include an outer layer, and the plurality of support sticks may be disposed inside the outer layer.

The auxetic structure may include a plurality of first areas and a plurality of second areas, and the plurality of first areas and the plurality of second areas may be disposed alternately with one another in a first direction in a state in which the display module is unrolled from the rolling shaft.

Among the plurality of first areas, a first area closest to the flat area may have a smaller width in the first direction than another first area adjacent to the first area in the state in which the display module is unrolled from the rolling shaft.

The plurality of second areas may have the same width in the first direction in the state in which the display module is unrolled from the rolling shaft.

The display device may further include an adhesive sheet that couples the rolling shaft and the display module, and the adhesive sheet may be bonded to the curved area of the rolling shaft and the side surface and an upper surface of the display module.

The adhesive sheet may be disposed between the rotational axis and the second area in the state in which the display module is rolled on the rolling shaft. The second area may completely cover the adhesive sheet.

According to an embodiment, a display device includes a rolling shaft having a rotational axis defined therein and including a side surface having a step defined thereon to extend in the same direction as the rotational axis and a display module coupled to the side surface of the rolling shaft to compensate for the step. The display module includes a display panel, an auxetic structure disposed below the display panel, and a support layer that is disposed below the auxetic structure and that includes a plurality of support sticks. The auxetic structure includes a first area including a first line that defines first unit cells and a second area including a second line that defines second unit cells. The step is disposed between the rotational axis and the second area in a state in which the display module is rolled on the rolling shaft. The second line has a greater line width than the first line, the second line has a greater thickness than the first line, or the second unit cells each have a smaller pitch than each of the first unit cells.

A cross-section of the rolling shaft perpendicular to the rotational axis may include a curved area disposed clockwise from a first point having a first radius to a second point having a second radius greater than the first radius and a straight area that is disposed between the first point and the second point of the curved area and is shorter than the curved area. The curved area may have a gradually increasing radius from the first point toward the second point in a clockwise direction.

The display device may further include an adhesive layer disposed between the display panel and the support layer, and the auxetic structure may be disposed inside the adhesive layer.

### BRIEF DESCRIPTION OF THE FIGURES

The above and other objects and features of the present disclosure will become apparent by describing in detail embodiments thereof with reference to the accompanying drawings.

FIGS. 1A and 1B are side views of a display device according to an embodiment of the present disclosure.

FIG. 2 is a sectional view of the display device according to an embodiment of the present disclosure.

FIG. 3A is a sectional view of a display panel according to an embodiment of the present disclosure.

FIG. 3B is a perspective view of a support layer according to an embodiment of the present disclosure.

FIG. 4A is a perspective view of a rolling shaft according to an embodiment of the present disclosure.

FIGS. 4B and 4C are sectional views of the display device according to an embodiment of the present disclosure.

FIG. 5A is a plan view of an auxetic structure according to an embodiment of the present disclosure.

FIG. 5B is a sectional view of the auxetic structure according to an embodiment of the present disclosure.

FIGS. 5C and 5D are enlarged plan views of the auxetic structure according to an embodiment of the present disclosure.

FIG. 6 is a plan view of the auxetic structure according to an embodiment of the present disclosure.

FIG. 7 is a sectional view of the display device according to an embodiment of the present disclosure.

FIG. 8 is a sectional view of the display device according to an embodiment of the present disclosure.

FIG. 9 is a block diagram illustrating an electronic device according to an embodiment.

### DETAILED DESCRIPTION

In this specification, when a component (or an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as “first”, “second”, “first-first”, “first-second” and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

“About” or “substantially the same” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially the same” can mean within one or more standard deviations, or within ±10%, 5% or 2% of the stated value. Hereinafter, embodiments of the present disclosure will be described with reference to the accompanying drawings.

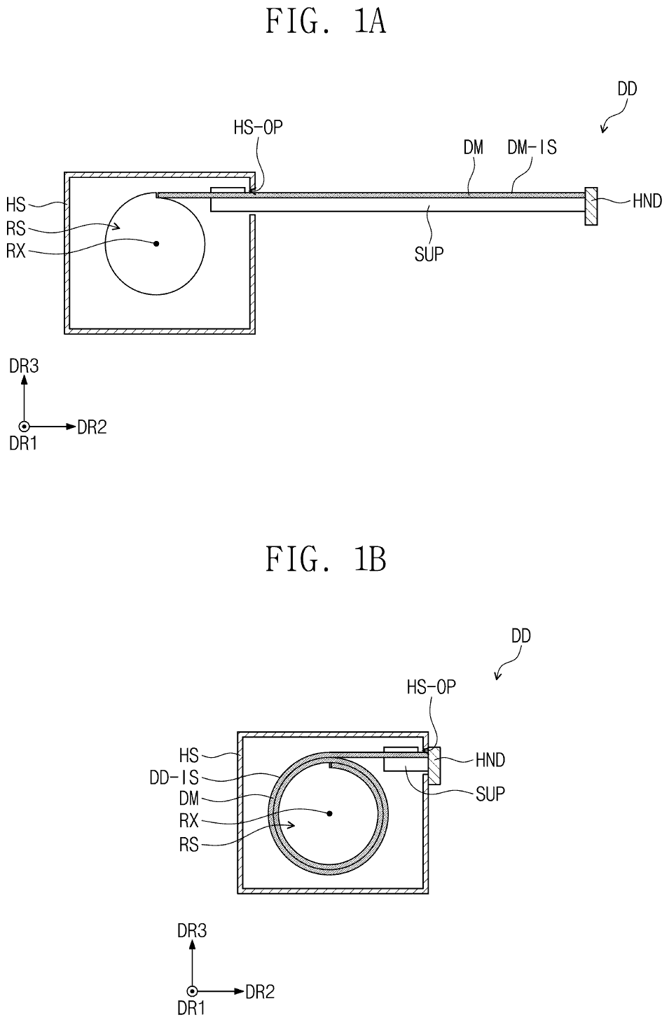

FIGS. 1A and 1B are side views of a display device DD according to an embodiment of the present disclosure.

FIG. 1A illustrates a state (a first state) in which a display module DM is unrolled from a rolling shaft RS, and FIG. 1B illustrates a state (a second state) in which the display module DM is rolled on the rolling shaft RS.

At least a portion of the display module DM may be accommodated in a housing HS, and the display module DM may enter and exit the housing HS through an opening HS-OP. One end of the display module DM may be connected to a handle HND. The display module DM may be guided by a support part SUP. The support part SUP may include an assembly of support frames that are withdrawn in stages during an unrolling operation.

The rolling shaft RS may have a shape extending in the first direction DR1. The rolling shaft RS may have a rotational axis RX defined therein. Substantially, the rotational axis RX extends in the first direction DR1.

In the first state, a display surface DM-IS of the display module DM is parallel to a plane defined by the first direction DR1 and the second direction DR2. The normal direction of the display surface DM-IS, that is, the thickness direction of the display module DM is indicated by the third direction DR3. Front surfaces (or upper surfaces) and rear surfaces (or lower surfaces) of members may be distinguished from each other based on the third direction DR3. Hereinafter, the first to third directions are directions indicated by first to third directional axes DR1, DR2, and DR3, respectively, and refer to the same reference numerals as the first to third directional axes DR1, DR2, and DR3.

The display surface DM-IS, when viewed in the third direction DR3, includes a display area where an image is displayed and a non-display area adjacent to the display area. Pixels are disposed in the display area, but are not disposed in the non-display area. For example, the display area may have a quadrangular shape. The non-display area may form the border of the display surface DM-IS while surrounding the display area.

According to the present disclosure, an auxetic structure that will be described below may be disposed to overlap at least an area of the display module DM that provides a curved display surface. For example, the auxetic structure may be disposed to entirely overlap the display area of the display module DM of FIG. 1A. Since the auxetic structure is disposed in the area having the curved surface, the auxetic structure may reduce stress caused by mechanical deformation of the display module DM while the display module DM is repeatedly changed between the first state and the second state.

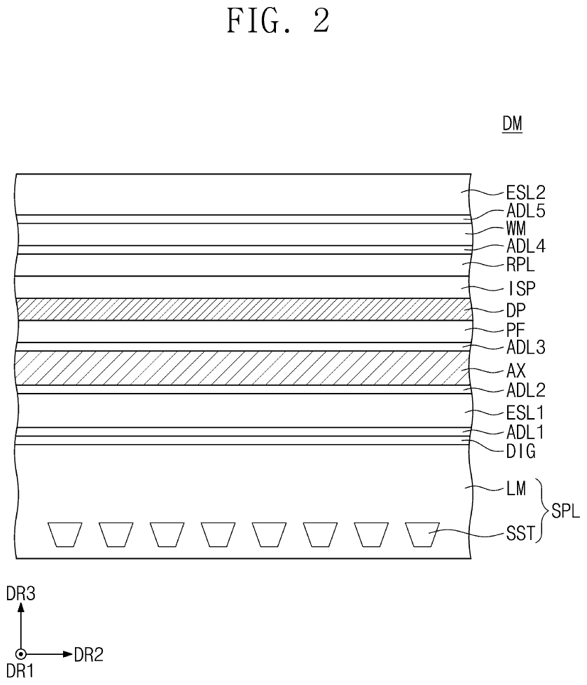

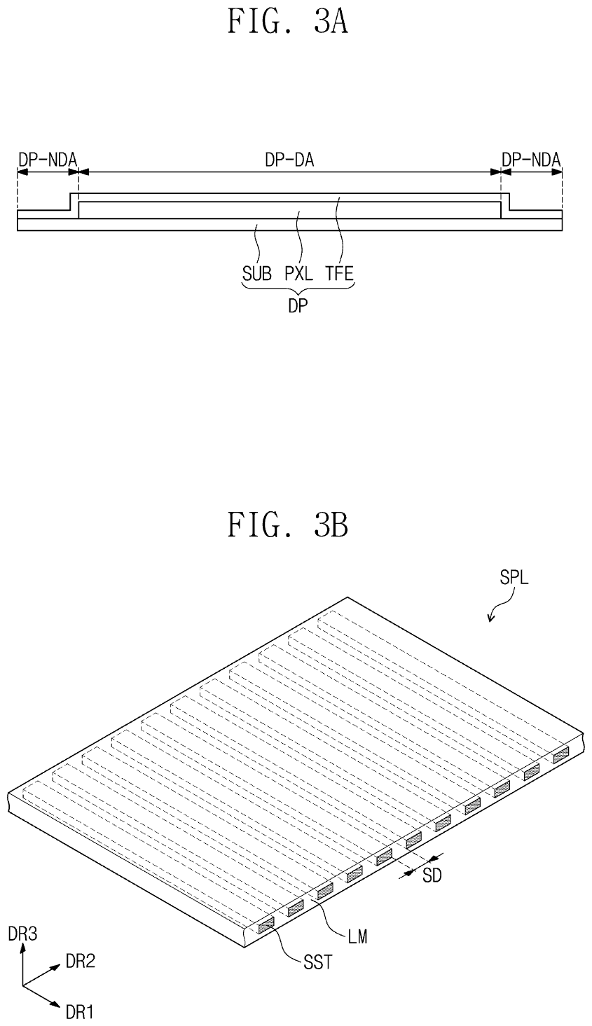

FIG. 2 is a sectional view of the display module DM according to an embodiment of the present disclosure. FIG. 3A is a sectional view of a display panel DP according to an embodiment of the present disclosure. FIG. 3B is a perspective view of a support layer SPL according to an embodiment of the present disclosure.

Referring to FIG. 2, the display module DM according to an embodiment of the present disclosure may include the support layer SPL, a digitizer DIG, a first elastic layer ESL1, the auxetic structure AX, a display panel protection layer PF, the display panel DP, an input sensor ISP, an anti-reflective layer RPL, a window WM, and a second elastic layer ESL2. In addition, the display module DM may further include first to fifth adhesive layers ADL1 to ADL5 disposed between the components of the display module DM to bond the components.

The components disposed above the display panel DP may be defined as an upper member, and the components disposed below the display panel DP may be defined as a lower member. The upper member may include the input sensor ISP, the anti-reflective layer RPL, the window WM and the second elastic layer ESL2. The lower member may include the support layer SPL, the digitizer DIG, the first elastic layer ESL1, the auxetic structure AX, and the display panel protection layer PF.

According to an embodiment of the present disclosure, at least one of the support layer SPL, the digitizer DIG, the first elastic layer ESL1, the display panel protection layer PF, the input sensor ISP, the anti-reflective layer RPL, the window WM, and the second elastic layer ESL2 may be omitted. In addition, it may be understood by those skilled in the art that the display module DM according to an embodiment of the present disclosure may further include other general-purpose components other than the components in FIG. 2.

The support layer SPL may be disposed below the display panel DP and may support the display panel DP. The digitizer DIG may be disposed below the display panel DP and may sense an external magnetic field signal. The position of the digitizer DIG may be changed.

The first elastic layer ESL1 may be disposed above the support layer SPL and may include an elastomer. For example, the first elastic layer ESL1 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, and polydimethylsiloxane (PDMS).

The auxetic structure AX may be disposed between the display panel DP and the support layer SPL. The auxetic structure AX may be bonded to the upper surface of the first elastic layer ESL1 by the second adhesive layer ADL2. The auxetic structure AX may be bonded to the lower surface of the display panel protection layer PF by the third adhesive layer ADL3. The second adhesive layer ADL2 and the third adhesive layer ADL3 may include a resin or a pressure sensitive adhesive (PSA) sheet. The second adhesive layer ADL2 and the third adhesive layer ADL3 may have a lower elastic modulus than the auxetic structure AX.

The auxetic structure AX may have a negative Poisson's ratio that enables elongation in a biaxial direction. The auxetic structure AX may have a Poisson's ratio of −0.9 to −0.1. However, the Poisson's ratio of the auxetic structure AX is not limited thereto. As the auxetic structure AX has a negative Poisson's ratio closed to 0, elongation characteristics and restoration characteristics may be improved. Although the display device DD including the auxetic structure AX having a single-layer structure is illustrated as an example, the display device DD may include an auxetic structure AX having a multi-layer structure.

The auxetic structure AX according to this embodiment may improve the rollability of the display module DM. Here, high rollability may mean that the display module DM is easily deformed (e.g., by a small external force) in the process of changing from the first state to the second state described with reference to FIGS. 1A and 1B and the display module DM is easily recovered in the process of changing from the second state to the first state.

The auxetic structure AX may include a non-magnetic material that does not react to a magnetic field. When the auxetic structure AX is formed of a non-magnetic material, the auxetic structure AX may not obstruct an operation of the digitizer DIG that recognizes a user input using a magnetic field. For example, the auxetic structure AX may include stainless steel.

The display panel DP may generate an image. The display panel DP may be a flexible display panel. The display panel DP according to an embodiment of the present disclosure may be an emissive display panel, but is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots and/or quantum rods.

The input sensor ISP may be disposed on the display panel DP. The input sensor ISP may include a plurality of sensor electrodes (not illustrated) for sensing an external input in a capacitance type. The input sensor ISP may be directly formed (or disposed) on the display panel DP. However, without being limited thereto, the input sensor ISP may be manufactured as a panel separate from the display panel DP and may be attached to the display panel DP by an adhesive layer. In an embodiment of the present disclosure, the input sensor ISP may be omitted.

The anti-reflective layer RPL may be directly formed (or disposed) on the input sensor ISP. However, without being limited thereto, the anti-reflective layer RPL may be coupled to the input sensor ISP by an adhesive layer. The anti-reflective layer RPL may be defined as a film for preventing reflection of external light. The anti-reflective layer RPL may decrease the reflectance of external light incident toward the display panel DP from above the display module DM.

When external light travelling toward the display panel DP is reflected from the display panel DP and provided back to a user, the user may visually recognize the external light as in a mirror. To prevent such a phenomenon, the anti-reflective layer RPL may include a plurality of color filters that display the same colors as those of the pixels of the display panel DP. The color filters may filter the external light into the same colors as those of the pixels. In this case, the external light may not be visible to the user.

In an embodiment of the present disclosure, the anti-reflective layer RPL may include a polarizer film for decreasing the reflectance of external light. The polarizer film may include a phase retarder and/or a polarizer. The color filters may be directly formed on the input sensor ISP. The polarizer film may be attached to the input sensor ISP by an adhesive layer. In an embodiment of the present disclosure, the anti-reflective layer RPL may be omitted.

The display panel protection layer PF may be disposed on the lower surface of the display panel DP and may protect the display panel DP from external impact. The display panel protection layer PF may have an elastic modulus of 1 GPa to 10 GPa. The display panel protection layer PF may have a thickness of 10 μm to 100 μm.

The window WM may be disposed on the anti-reflective layer RPL. The window WM may be bonded to the upper surface of the anti-reflective layer RPL by the fourth adhesive layer ADL4. The window WM may protect the display panel DP, the input sensor ISP, and the anti-reflective layer RPL from external scratches and impacts.

The second elastic layer ESL2 may be bonded to the upper surface of the window WM by the fifth adhesive layer ADL5. The second elastic layer ESL2 may be disposed above the window WM and may include an elastomer. For example, the second elastic layer ESL2 may include one of the materials that are able to be selected as the material of the first elastic layer ESL1.

Referring to FIG. 3A, the display panel DP may include a base layer SUB, a pixel layer PXL, and a thin film encapsulation layer TFE. The base layer SUB may include a display area DP-DA and a non-display area DP-NDA around the display area DP-DA. The display area DP-DA and the non-display area DP-NDA may correspond to the display area and the non-display area of the display module DM described with reference to FIGS. 1A and 1B.

The base layer SUB may include a flexible plastic substrate. For example, the base layer SUB may include a flexible plastic material such as polyimide (PI). The pixel layer PXL may be disposed in the display area DP-DA. The pixel layer PXL may include a plurality of pixels, and each of the pixels may include a pixel driving circuit and a light emitting element. The thin film encapsulation layer TFE may include at least two inorganic layers and an organic layer disposed between the inorganic layers. The inorganic layers may include an inorganic material and may protect the pixel layer PXL from moisture/oxygen. The organic layer may include an organic material and may protect the pixel layer PXL from foreign matter such as dust particles.

Referring to FIG. 3B, the support layer SPL may include support sticks SST and an outer layer LM. The support sticks SST may extend in the same direction as the rotational axis RX of FIGS. 1A and 1B. The plurality of support sticks SST may extend in the first direction DR1 and may be arranged in the second direction DR2. Adjacent support sticks SST are spaced apart from each other to prevent interference between the adjacent support sticks SST in the second state of FIG. 1B. The area between the adjacent support sticks SST may be defined as a separation area SD. The distances between the separation areas SD in the second direction DR2 may be the same, but are not necessarily limited thereto.

The plurality of support sticks SST may have a rigid property. For example, the plurality of support sticks SST may include metal. The support sticks SST may include aluminum, stainless steel, or invar. Furthermore, the support sticks SST may include metal that is attracted to a magnet. Although the plurality of support sticks SST having a rectangular cross-section are illustrated as an example in FIG. 3B, the present disclosure is not limited thereto. The plurality of support sticks SST may have a trapezoidal cross-section as illustrated in FIG. 2.

The outer layer LM may absorb stress caused by the plurality of support sticks SST when the display module DM (refer to FIGS. 1A and 1B) is repeatedly deformed. The outer layer LM may fix the plurality of support sticks SST spaced apart from each other. As illustrated in FIG. 3B, the plurality of support sticks SST may be disposed inside the outer layer LM. However, without being limited thereto, only portions of the plurality of support sticks SST may be disposed inside the outer layer LM.

The outer layer LM may include an elastomer having elasticity. For example, the outer layer LM may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, and polydimethylsiloxane (PDMS). However, the material of the outer layer LM is not limited thereto.

The support sticks SST may have a higher elastic modulus than the outer layer LM. The outer layer LM may have an elastic modulus of 20 KPa to 20 MPa. The support sticks SST may have an elastic modulus of 1 GPa to 200 GPa. The support sticks SST having a relatively high rigidity may support the display module DM, and the outer layer LM having a relatively high elasticity may provide a flat support surface for the display module DM.

When the outer layer LM is not used and the support sticks SST are attached to the lower surface of the display module DM to support the display module DM, the display module DM may be deformed in the spaces between the support sticks SST. For example, when the display module DM is repeatedly deformed between the first state of FIG. 1A and the second state of FIG. 1B, portions of the display module DM that overlap the separation areas SD may be deformed. The deformation of the display module DM may be visually recognized as creases. That is, the surface quality of the display module DM may be degraded.

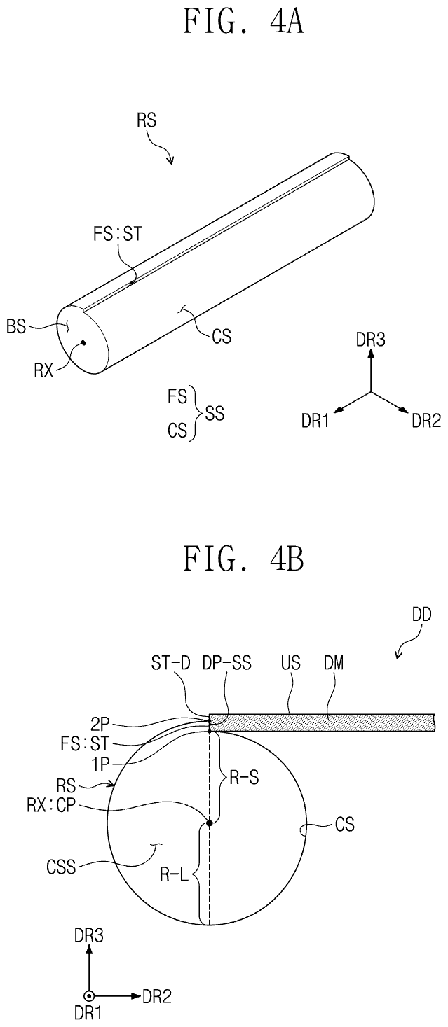

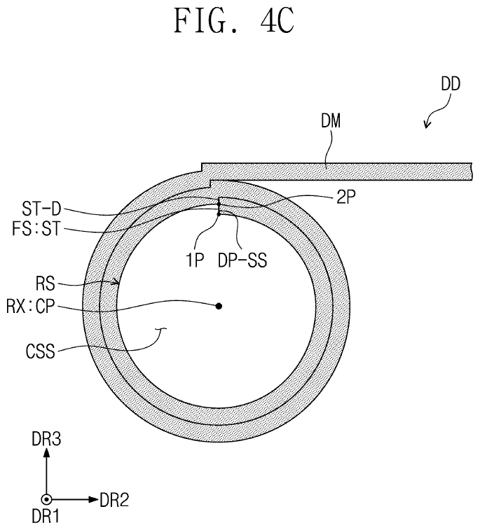

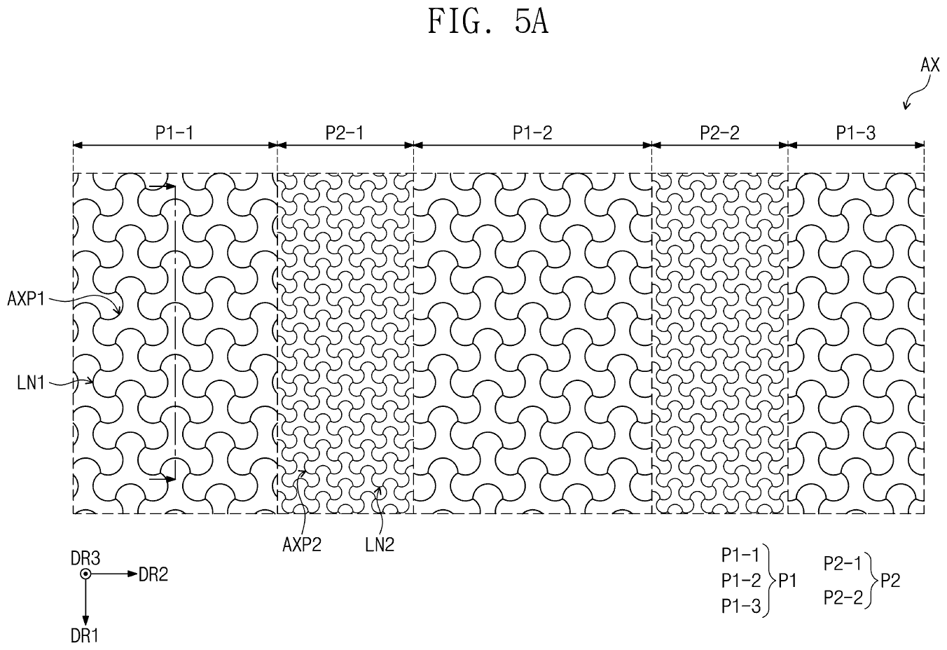

FIG. 4A is a perspective view of the rolling shaft RS according to an embodiment of the present disclosure. FIGS. 4B and 4C are sectional views of the display device DD according to an embodiment of the present disclosure. In FIGS. 4B and 4C, some of the components of the display device DD illustrated in FIGS. 1A and 1B are not illustrated.

As illustrated in FIG. 4A, the rotational axis RX extending in the first direction DR1 is defined inside the rolling shaft RS. The rolling shaft RS includes a side surface SS and two bottom surfaces BS. The rolling shaft RS may have a substantially cylindrical shape, and the rotational axis RX may correspond to the centers of the two bottom surfaces BS of the rolling shaft RS.

A step ST extending in the same direction as the rotational axis RX is defined on the side surface SS. The step ST is formed by a flat area FS that severs the continuity of a curved area CS. The flat area FS is disposed between the two bottom surfaces BS of the rolling shaft RS. The flat area FS may have a constant width in a direction perpendicular to the first direction DR1, for example, in the third direction DR3 in FIG. 4A.

Referring to FIGS. 4A to 4C, when the display module DM is coupled to the side surface SS, the step ST of the rolling shaft RS decreases a step ST-D formed by the display module DM and the rolling shaft RS. This is because the display module DM is coupled to the side surface SS of the rolling shaft RS to compensate for the step ST of the rolling shaft RS (remove or decrease the step ST). The display module DM may be coupled to the side surface SS (e.g., flat area FS) by an adhesive. One side surface DP-SS of the display module DM is disposed to face the flat area FS. The side surface DP-SS of the display module DM may make contact with the flat area FS.

In FIGS. 4B and 4C, the cross-section CSS of the rolling shaft RS is illustrated. The cross-section CSS is defined by the second direction DR2 and the third direction DR3. In the cross-section CSS, the curved area CS covers a long distance from a first point 1P having a first radius R-S to a second point 2P having a second radius R-L greater than the first radius R-S in a clockwise direction. The radius of the curved area CS may be gradually (or linearly) increased from the first point 1P toward the second point 2P along the curved area CS in a clockwise direction. In other words, the radius of the curved area CS in the cross-section CSS may be increased from the first radius R-S to the second radius R-L in the clockwise direction. In the cross-section CSS, the flat area FS is located at a straight line connecting the first point 1P and the second point 2P in the shortest distance.

The above-described step ST-D formed by the display module DM may be caused by the difference between the thickness of the display module DM and the depth (or height) of the step ST. Since a process error may occur in a process of forming the step ST on the rolling shaft RS or an error may occur in a manufacturing process of the display module DM, the thickness of the display module DM and the depth (or height) of the step ST may be different from each other. The step ST-D between the curved area CS of the rolling shaft RS at the second point 2P and the upper surface US of the display module DM may occur at a position adjacent to the step ST of the rolling shaft RS. When the side surface DP-SS of the display module DM makes contact with the flat area FS, the step ST-D between the curved area CS of the rolling shaft RS at the second point 2P and the upper surface US of the display module DM may occur at the same position as the step ST of the rolling shaft RS.

In this embodiment, the thickness of the display module DM may be greater than the step ST. However, the reverse may be possible. In this case, the second point 2P of the rolling shaft RS may be located farther away from the center CP of the cross-section CSS than the upper surface US of the display module DM that is adjacent to the second point 2P of the rolling shaft RS.

As illustrated in FIG. 4C, a portion of the display module DM overlaps the steps ST and ST-D in the state in which the display module DM is rolled on the rolling shaft RS. The steps ST and ST-D are located between the portion of the display module DM and the rotational axis RX of the rolling shaft RS. That is, the flat area FS is located between the portion of the display module DM and the center CP of the cross-section CSS.

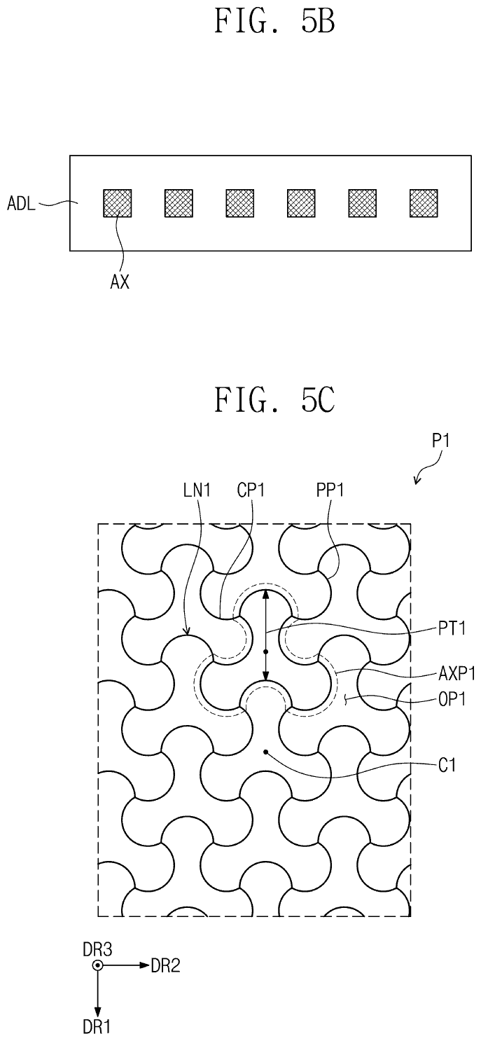

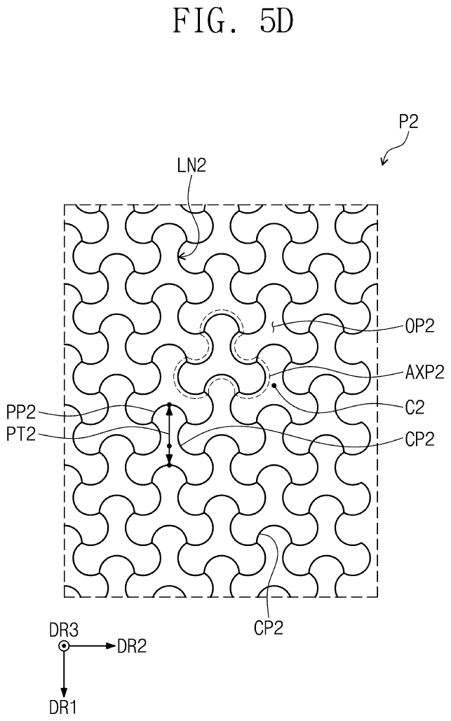

FIG. 5A is a plan view of the auxetic structure AX according to an embodiment of the present disclosure. FIG. 5B is a sectional view of the auxetic structure AX according to an embodiment of the present disclosure. FIGS. 5C and 5D are enlarged plan views of the auxetic structure AX according to an embodiment of the present disclosure.

Referring to FIG. 5A, the auxetic structure AX may have different elastic moduli depending on areas. The auxetic structure AX may include a first area P1 and a second area P2 having a higher elastic modulus than the first area P1. The first area P1 may have an elastic modulus of 50 MPa to 400 MPa, and the second area P2 may have an elastic modulus of 500 MPa to 1 GPa. The auxetic structure AX may include a plurality of first areas P1 and a plurality of second areas P2. The plurality of first areas P1 and the plurality of second areas P2 may alternate with one another in the second direction DR2 in the state (the first state) in which the display module DM is unrolled from the rolling shaft RS.

The plurality of first areas P1 may include a first-first area P1-1, a first-second area P1-2, and a first-third area P1-3. The plurality of second areas P2 may include a second-first area P2-1 and a second-second area P2-2. Among the plurality of first areas P1 and the plurality of second areas P2, the first-first area P1-1 may be disposed closest to the flat area FS illustrated in FIGS. 4A to 4C.

The first-second area P1-2 may have a greater width than the first-first area P1-1. The widths of the plurality of first areas P1 are measured in the second direction DR2. This is because the first-second area P1-2 is disposed at a position having a greater radius than the first-first area P1-1. In this embodiment, the first-third area P1-3 has a smaller width in the second direction DR2 than each of the first-first area P1-1 and the first-second area P1-2, but is not limited thereto.

The second-first area P2-1 and the second-second area P2-2 may have the same width. The widths of the plurality of second areas P2 are measured in the second direction DR2. Since it is sufficient that the second-first area P2-1 and the second-second area P2-2 overlap the step ST even though located at different radii, the second-first area P2-1 and the second-second area P2-2 may have the same width. Each of the second-first area P2-1 and the second-second area P2-2 may have a width of 1 millimeter (mm) to 3 mm in the second direction DR2.

The second-first area P2-1 and the second-second area P2-2 overlap each other in the state (the second state) in which the display module DM is rolled on the rolling shaft RS as illustrated in FIG. 4C. The step ST, that is, the flat area FS is disposed between the rotational axis RX and the second-first area P2-1. In the second state, the step ST is also disposed between the rotational axis RX and the second-second area P2-2.

Since the second areas P2-1 and P2-2 having a relatively high elastic modulus overlap the area where the step ST-D is formed between the side surface of the rolling shaft RS and the upper surface of the display module DM, deformation caused by the step ST-D may be effectively prevented from being transferred to the display module DM of FIG. 4C. That is, the step ST-D between the side surface of the rolling shaft RS and the upper surface of the display module DM may be effectively prevented from generating a crease (or wrinkle) in the display module DM.

According to an experimental example, it can be seen that a crease of about 70 μm occurs when the display module DM including the auxetic structure AX having an elastic modulus of 80 MPa is rolled on the rolling shaft RS on which the above-described step ST-D is formed. The occurrence or non-occurrence of a crease may be identified by measuring the height between a reference surface and the upper surface of the display module DM. The height between the upper surface of the display module DM and the reference surface when a crease does not occur is selected as a reference value. When a crease occurs, the height between the upper surface of the display module DM and the reference surface is greater than the reference value. The above-described 70 μm is a value obtained by subtracting the reference value from the height between the upper surface of the display module DM having the auxetic structure AX and the reference surface.

According to an experimental example, it can be seen that a crease of about 59 μm occurs when the display module DM including the auxetic structure AX having an elastic modulus of 230 MPa is rolled on the rolling shaft RS on which the above-described step ST-D is formed. According to an experimental example, it can be seen that a crease of about 37 μm occurs when the display module DM including the auxetic structure AX having an elastic modulus of 949 MPa is rolled on the rolling shaft RS on which the above-described step ST-D is formed.

In the three experimental examples described above, the configurations of the display module DM except for the auxetic structure AX are all the same. According to the three experimental examples described above, it can be seen that the height of the crease is decreased as the elastic modulus of the auxetic structure AX is increased.

However, when the auxetic structure AX has an elastic modulus of 400 MPa or more, the rollability of the display module DM may be decreased, and the rolling radius of the display module DM may be increased. In addition, when the auxetic structure AX has a constant elastic modulus (e.g., an elastic modulus of 400 MPa or more) irrespective of areas, the rollability of the display module DM may be further decreased, and the rolling radius of the display module DM may be increased.

According to this embodiment, the auxetic structure AX may include an area having a relatively low elastic modulus and thus may suppress the above-described side effects. As illustrated in FIG. 5A, the auxetic structure AX may include the first-first area P1-1, the first-second area P1-2, and the third area P1-3 that have a relatively low elastic modulus compared to each of the second-first area P2-1 and the second-second area P2-2. Accordingly, the rollability of the display module DM may be increased, and the rolling radius of the display module DM may be decreased.

As illustrated in FIG. 5B, the auxetic structure AX may be disposed inside an adhesive layer ADL. The adhesive layer ADL may surround all surfaces of the auxetic structure AX. The adhesive layer ADL may replace the second adhesive layer ADL2 and the third adhesive layer ADL3 of FIG. 2.

The adhesive layer ADL may be formed of an optically clear resin in an amorphous liquid form. An acrylic adhesive material, a silicone-based adhesive material, and a urethane-based adhesive material may be used for the adhesive layer ADL. However, without being limited thereto, the adhesive layer ADL may be formed of adhesive materials having various shapes and materials.

A first optically clear resin layer is formed on one of the upper surface of the first elastic layer ESL1 and the lower surface of the display panel protection layer PF of FIG. 2. The auxetic structure AX is impregnated in the first optically clear resin layer. A second optically clear resin layer is formed on the first optically clear resin layer to cover the auxetic structure. When a curing process is performed, the first optically clear resin layer and the second optically clear resin layer may be cured to form the adhesive layer ADL of FIG. 5B. The curing process is not limited to a single process. A curing process may be performed after the auxetic structure is impregnated in the first optically clear resin layer, and an additional curing process may be performed after the second optically clear resin layer is formed.

As illustrated in FIGS. 5C and 5D, the auxetic structure AX may have different structures depending on areas. FIG. 5C illustrates an enlarged view of the first area P1, and FIG. 5D illustrates an enlarged view of the second area P2.

As illustrated in FIG. 5C, the auxetic structure AX may include a first line LN1 disposed in the first area P1. The first line LN1 may be formed by etching a metal plate or may be formed by an ink-jet printing method. The first line LN1 may define a plurality of first unit cells AXPL. Each of the plurality of first unit cells AXP1 corresponds to an auxetic pattern. The first unit cell AXP1 has a closed curve shape, and an opening OP1 is defined in the first unit cell AXPL.

In FIG. 5C, an auxetic pattern having a star shape is illustrated as the first unit cell AXP1. The star-shaped auxetic pattern illustrated in FIG. 5C may have a Poisson's ratio of −0.1. The Poisson's ratio may be determined depending on the shape of the auxetic pattern. However, without being limited thereto, the first unit cell AXP1 may be modified into other shapes such as a re-entrant shaped auxetic pattern.

The first unit cell AXP1 may include a plurality of first protrusions PP1 and a plurality of first depressions CP1. In this embodiment, a star-shaped auxetic pattern including three first protrusions PP1 and three first depressions CP1 is illustrated as an example. According to an embodiment of the present disclosure, a star-shaped auxetic pattern including a larger number of first protrusions PP1 and a larger number of first depressions CP1 may be applied to the first unit cell AXP1.

The plurality of first protrusions PP1 may have the same maximum separation distance from the center C1 of the first unit cell AXP1. The plurality of first depressions CP1 may have the same minimum separation distance from the center C1 of the first unit cell AXP1. The first depressions CP1 of the first unit cell AXP1 may share the same portion of the first line LN1 with the first protrusions PP1 of another unit cell adjacent to the first unit cell AXP1.

In this embodiment, the three first protrusions PP1 and the three first depressions CP1 may alternate with one another in the clockwise direction. The three first protrusions PP1 may be arranged at a constant angle with the center C1 of the first unit cell AXP1 as a rotational axis. One first protrusion PP1 may overlap another first protrusion PP1 when the first unit cell AXP1 is rotated about the center C1 by the constant angle. The three first depressions CP1 may be arranged at the constant angle with the center C1 of the first unit cell AXP1 as a rotational axis. One first depression CP1 may overlap another first depression CP1 when the first unit cell AXP1 is rotated about the center C1 by the constant angle.

A first pitch PT1 will be described based on two first unit cells AXP1 adjacent to each other. The distance between the first protrusion PP1 and the first depression CP1 disposed on the same line may be defined as the first pitch PT1. The first pitch PT1 is measured to pass through the center C1 of the first unit cell AXP1.

Referring to FIG. 5D, the auxetic structure AX may include a second line LN2 disposed in the second area P2. The second line LN2 may be formed by the same method as one of the methods of forming the first line LN1 and may be formed in the same process.

The second line LN2 may define a plurality of second unit cells AXP2. Each of the plurality of second unit cells AXP2 corresponds to an auxetic pattern. The second unit cell AXP2 has a closed curve shape, and an opening OP2 is defined in the second unit cell AXP2.

In FIG. 5D, the second unit cell AXP2 that has the same shape as the first unit cell AXP1, but has a pitch (or an area) different from that of the first unit cell AXP1 is illustrated. The second unit cell AXP2 may also be an auxetic pattern having a star shape and may have a Poisson's ratio of −0.1. The second unit cell AXP2 including three second protrusions PP2 and three second depressions CP2 is illustrated as an example.

A second pitch PT2 will be described based on two second unit cells AXP2 adjacent to each other. The distance between the second protrusion PP2 and the second depression CP2 disposed on the same line may be defined as the second pitch PT2.

As described with reference to FIG. 5A, the first area P1 and the second area P2 may have different elastic moduli. The elastic moduli may be determined depending on the line widths and thicknesses of the first line LN1 and the second line LN2 and may be determined depending on the pitches of the first unit cell AXP1 and the second unit cell AXP2.

When the first line LN1 and the second line LN2 have the same line width and thickness, the elastic moduli of the first area P1 and the second area P2 may be determined depending on the pitches of the first unit cell AXP1 and the second unit cell AXP2. According to this embodiment, since the pitch of the first unit cell AXP1 is greater than the pitch of the second unit cell AXP2, the first area P1 may have a lower elastic modulus than the second area P2.

According to an embodiment of the present disclosure, when the first unit cell AXP1 formed of the first line LN1 having a thickness of 50 μm and a line width of 80 μm has a pitch of 900 μm, the first area P1 may have an elastic modulus of 80 MPa. When the second unit cell AXP2 formed of the second line LN2 having a thickness of 50 μm and a line width of 80 μm has a pitch of 450 μm, the second area P2 may have an elastic modulus of 949 MPa.

When the first line LN1 has a smaller thickness or line width than the second line LN2 even though the first unit cell AXP1 and the second unit cell AXP3 have the same pitch, the first area P1 may have a lower elastic modulus than the second area P2. According to an embodiment of the present disclosure, the first line LN1 may have a line width of 30 μm to 60 μm, and the second line LN2 may have a line width of 60 μm to 100 μm.

The first line LN1 and the second line LN2 may have a thickness of 10 μm to 500 μm, and the thickness of the first line LN1 and the thickness of the second line LN2 may be set to achieve desired elastic moduli in consideration of the pitches of the first unit cell AXP1 and the second unit cell AXP2 and the line widths of the first line LN1 and the second line LN2. When the first unit cell AXP1 and the second unit cell AXP2 have the same pitch and the first line LN1 and the second line LN2 have the same line width, the first area P1 may have a lower elastic modulus than the second area P2 if the first line LN1 is formed to be thinner than the second line LN2. In an embodiment, the thickness of the first line LN1 may be thinner than the thickness of the second line LN2.

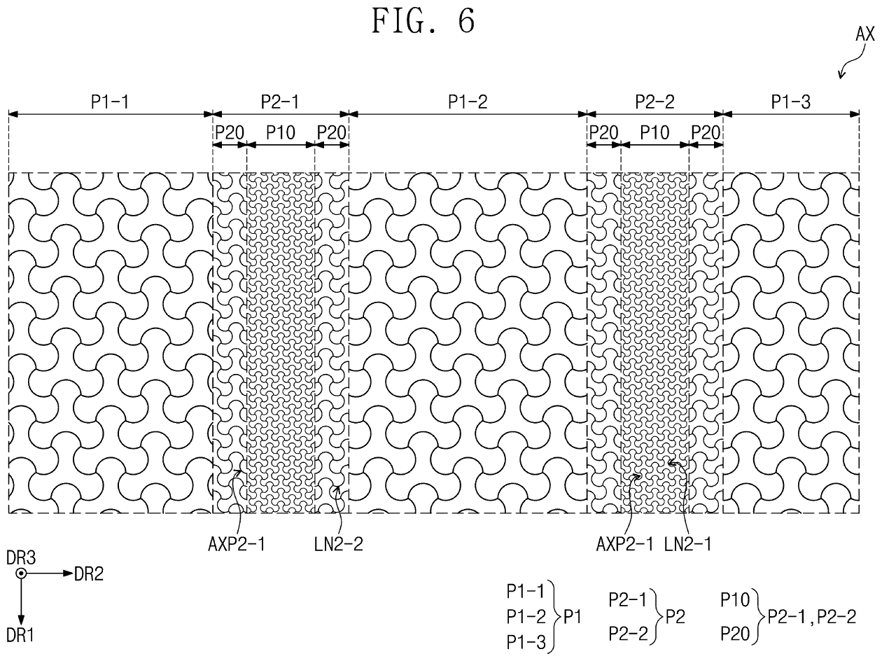

FIG. 6 is a plan view of the auxetic structure AX according to an embodiment of the present disclosure. The following description will be focused on the difference from the auxetic structure AX of FIG. 5A, and detailed description of the same components refers to the description of FIG. 5A.

As illustrated in FIG. 6, the second area P2 may include a first modulus area P10 and second modulus areas P20. The second modulus areas P20 are disposed on the opposite sides of the first modulus area P10 in the state in which the display module DM is unrolled from the rolling shaft RS as illustrated in FIG. 4B.

The first modulus area P10 has a higher elastic modulus than the second modulus areas P20. The second modulus areas P20 have a higher elastic modulus than the first area P1. The first modulus area P10 overlaps the step ST of the rolling shaft RS in the state in which the display module DM is rolled on the rolling shaft RS as illustrated in FIG. 4C. The second modulus areas P20 may decrease the difference in elastic modulus between the first area P1 and the second area P2, thereby increasing the rollability of the display module DM.

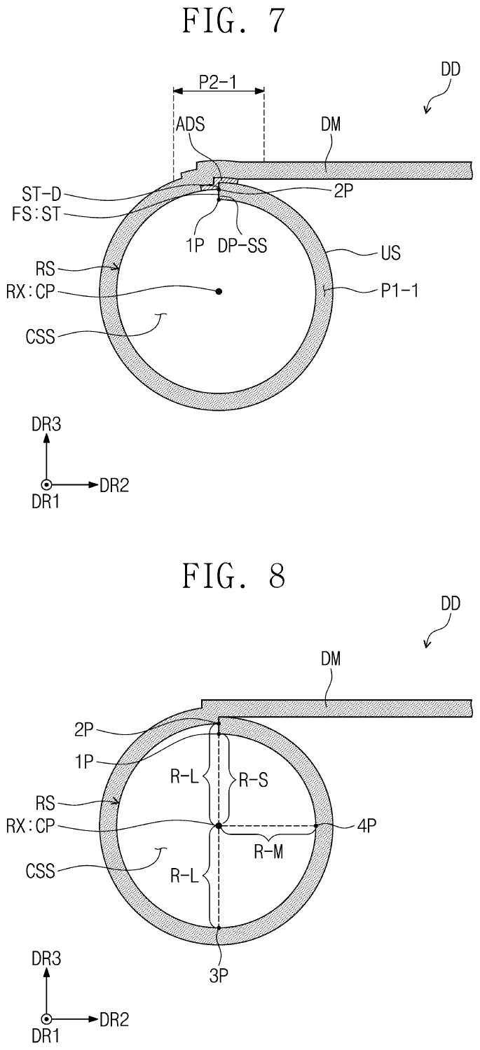

FIGS. 7 and 8 are sectional views of the display device DD according to an embodiment of the present disclosure. The following description will be focused on the difference from the display device DD of FIGS. 4A to 4C, and detailed description of the same components refers to the description of FIGS. 4A to 4C.

Referring to FIG. 7, the display module DM rolled once on the rolling shaft RS is additionally illustrated. In addition, the positions of the first-first area P1-1 and the second-first area P2-1 of the auxetic structure AX illustrated in FIG. 5A relative to the display module DM are illustrated.

The display device DD may further include an adhesive sheet ADS that couples the rolling shaft RS and the display module DM. The adhesive sheet ADS is bonded to the curved area CS of the rolling shaft RS and the side surface DP-SS at the step ST-D and the upper surface US of the display module DM. The adhesive sheet ADS increases the coupling force between the rolling shaft RS and the display module DM.

In the state in which the display module DM is rolled on the rolling shaft RS, the adhesive sheet ADS may be disposed between the rotational axis RX and the second-first area P2-1, and the second-first area P2-1 may completely cover the adhesive sheet ADS. The second-first area P2-1 may cover steps formed on the opposite sides of the adhesive sheet ADS in the second direction DR2 by the adhesive sheet ADS.

Referring to FIG. 8, in the cross-section CSS of the rolling shaft RS, the curved area CS is located clockwise from the first point 1P having the first radius R-S to the second point 2P having the second radius R-L greater than the first radius R-S.

A third point 3P is disposed between the first point 1P and the second point 2P on the curved area CS in a clockwise direction. The first point 1P and the second point 2P disposed on the curved area CS in the 12 o'clock direction are illustrated, and the third point 3P disposed on the curved area CS in the 6 o'clock direction is illustrated as an example. The radius of the curved area CS may be gradually increased from the first point 1P toward the third point 3P. The radius of the curved area CS may be increased in the clockwise direction from the first radius R-S of the first point 1P to the second radius R-L of the third point 3P. A fourth point 4P disposed on the curved area CS in the 3 o'clock direction may have a third radius R-M that is a middle value between the first radius R-S and the second radius R-L.

The third point 3P may have the same second radius R-L as the second point 2P. The cross-section CSS may have the same second radius R-L from the third point 3P to the second point 2P. When the area between the first point 1P and the third point 3P of the curved area CS where the radius increases is defined as a first area, the area between the third point 3P and the second point 2P of the curved area CS where the radius is constant may be defined as a second area. The position of the third point 3P is not limited to the 6 o'clock direction and may be changed depending on embodiments.

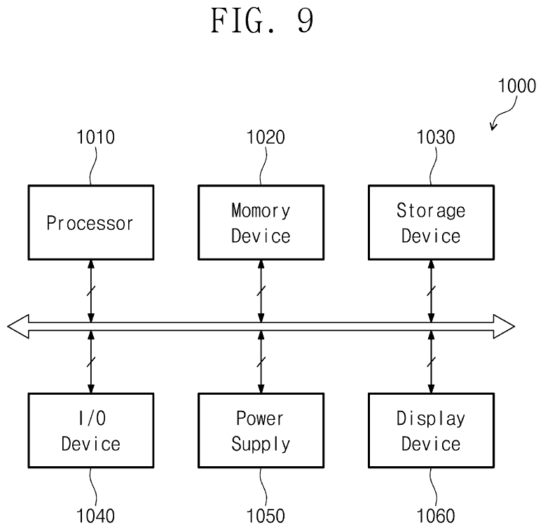

FIG. 9 is a block diagram illustrating an electronic device according to an embodiment.

Referring to FIG. 9, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIGS. 1A to 8. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

According to the present disclosure, the second area of the auxetic structure that has a relatively high elastic modulus may cover the step of the rolling shaft to prevent the step from being transferred to the display module. Accordingly, creases in the display device may be reduced.

In addition, the first area of the auxetic structure that has a relatively low elastic modulus may increase the rollability of the display device.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a rolling shaft including a side surface including a curved area and a flat area; and
a display module coupled to the side surface of the rolling shaft such that a side surface of the display module faces the flat area,
wherein the display module includes:
a display panel;
an auxetic structure disposed below the display panel; and
a support layer disposed below the auxetic structure, the support layer including a plurality of support sticks,
wherein the auxetic structure includes:
a first area; and
a second area having a higher elastic modulus than the first area,
wherein a rotational axis is defined in the rolling shaft, and
wherein the flat area is disposed between the rotational axis and the second area in a state in which the display module is rolled on the rolling shaft.

2. The display device of claim 1, wherein the first area has an elastic modulus of 50 megapascals (MPa) to 400 MPa, and
wherein the second area has an elastic modulus of 500 MPa to 1 gigapascal (GPa).

3. The display device of claim 1, wherein the curved area is disposed clockwise from a first point having a first radius to a second point having a second radius greater than the first radius on a cross-section perpendicular to the rotational axis, and
wherein the curved area has a gradually increasing radius from the first point toward the second point in a clockwise direction.

4. The display device of claim 1, wherein the curved area is disposed clockwise from a first point having a first radius to a second point having a second radius greater than the first radius on a cross-section perpendicular to the rotational axis, and
wherein the curved area includes a first area having a gradually increasing radius from the first point to a third point between the first point and the second point in a clockwise direction and a second area having a constant radius from the third point to the second point in the clockwise direction.

5. The display device of claim 1, wherein the auxetic structure includes:
a first line defining first unit cells disposed in the first area; and
a second line defining second unit cells disposed in the second area, and
wherein the second line has a greater line width than the first line.

6. The display device of claim 5, wherein the first unit cells and the second unit cells have substantially the same pitch.

7. The display device of claim 5, wherein the first line has a line width of 30 micrometers (μm) to 60 μm, and
wherein the second line has a line width of 60 μm to 100 μm.

8. The display device of claim 1, wherein the auxetic structure includes:
a first line defining first unit cells disposed in the first area; and
a second line defining second unit cells disposed in the second area, and
wherein the second unit cells each have a smaller pitch than each of the first unit cells.

9. The display device of claim 8, wherein the first line and the second line have substantially the same line width or substantially the same thickness.

10. The display device of claim 1, wherein the second area includes:
a first modulus area; and
second modulus areas disposed on opposite sides of the first modulus area in a state in which the display module is unrolled from the rolling shaft, and
wherein the first modulus area has a higher elastic modulus than the second modulus areas.

11. The display device of claim 1, further comprising:
an adhesive layer disposed between the display panel and the support layer,
wherein the auxetic structure is disposed inside the adhesive layer.

12. The display device of claim 1, wherein the support layer further includes an outer layer, and the plurality of support sticks are disposed inside the outer layer.

13. The display device of claim 1, wherein the auxetic structure includes a plurality of first areas and a plurality of second areas, and
wherein the plurality of first areas and the plurality of second areas are disposed alternately with one another in a certain direction in a state in which the display module is unrolled from the rolling shaft.

14. The display device of claim 13, wherein among the plurality of first areas, a first area closest to the flat area has a smaller width in the certain direction than another first area adjacent to the first area in the state in which the display module is unrolled from the rolling shaft.

15. The display device of claim 13, wherein the plurality of second areas have a same width in the certain direction in the state in which the display module is unrolled from the rolling shaft.

16. The display device of claim 1, further comprising:
an adhesive sheet coupling the rolling shaft and the display module,
wherein the adhesive sheet is bonded to the curved area of the rolling shaft and the side surface and an upper surface of the display module.

17. The display device of claim 16, wherein the adhesive sheet is disposed between the rotational axis and the second area in the state in which the display module is rolled on the rolling shaft, and
wherein the second area completely covers the adhesive sheet.

18. A display device comprising:
a rolling shaft including a side surface having a step defined thereon and configured to rotate around a rotational axis therein, the step extending in a same direction as the rotational axis; and
a display module coupled to the side surface of the rolling shaft to compensate for the step,
wherein the display module includes:
a display panel;
an auxetic structure disposed below the display panel; and
a support layer disposed below the auxetic structure, the support layer including a plurality of support sticks,
wherein the auxetic structure includes:
a first area including a first line defining first unit cells; and
a second area including a second line defining second unit cells,
wherein the step is disposed between the rotational axis and the second area in a state in which the display module is rolled on the rolling shaft, and
wherein the second line has a greater line width than the first line, the second line has a greater thickness than the first line, or the second unit cells each have a smaller pitch than each of the first unit cells.

19. The display device of claim 18, wherein a cross-section of the rolling shaft perpendicular to the rotational axis includes:
a curved area disposed clockwise from a first point having a first radius to a second point having a second radius greater than the first radius; and
a straight area disposed between the first point and the second point of the curved area, the straight area being shorter than the curved area, and
wherein the curved area has a gradually increasing radius from the first point toward the second point in a clockwise direction.

20. An electric device comprising:
a display device; and
a power supply configured to provide power to the display device,
wherein the display device comprises:
a rolling shaft including a side surface including a curved area and a flat area; and
a display module coupled to the side surface of the rolling shaft such that a side surface of the display module faces the flat area,
wherein the display module includes:
a display panel;
an auxetic structure disposed below the display panel; and
a support layer disposed below the auxetic structure, the support layer including a plurality of support sticks,
wherein the auxetic structure includes:
a first area; and
a second area having a higher elastic modulus than the first area,
wherein a rotational axis is defined in the rolling shaft, and
wherein the flat area is disposed between the rotational axis and the second area in a state in which the display module is rolled on the rolling shaft.
